(19) United States
(12) Patent Application Publication
(10) Pub. No.: US 2010/0006146 A1
(43) Pub. Date: Jan. 14, 2010

(54) Wafer-Specific Line Patterning For Solar Cells And The Like

(75) Inventors: Scott Limb, Palo Alto, CA (US); Francisco Torres, San Jose, CA (US)

Correspondence Address: JAS IP CONSULTING, 309 2ND STREET, SUITE 8, LOS ALTOS, CA, 94022, US

(73) Assignee: Palo Alto Research Center Incorporated, Palo Alto, CA (US)

(21) Appl. No.: 12/169,377

(22) Filed: Jul. 8, 2008

(51) Int. Cl. H01L 31/00

(52) U.S. Cl. 136/256

(57) ABSTRACT

A semiconductor or similar body used, for example, for a solar cell is examined for the physical locations of characteristics effecting its performance, such as grain boundaries, areas of relatively higher sheet resistance, bulk resistance, shortened carrier lifetime, etc. A grid array layout for conductive lines may be specifically tailored such it is positioned over less efficient photo-generative regions of the body to, for example, minimize shadowing of more efficient regions, provide a short conduction path for regions of shortened carrier lifetime, etc. The grid array layout may then be formed on the surface of the body, for example by a digital lithographic process, to accommodate cell-by-cell and/or body-by-body variations in the performance characteristics. The tailored grid array provides increased overall photo-generative efficiency of the completed solar cell.

### BACKGROUND

The present invention is related to photovoltaic and solar cells, and more specifically to methods for producing the printed pattern of interconnection lines on the surface of such cells.

The efficiencies and economies of scale of solar cell manufacturing have improved at a rapid pace in recent years. However, there is a constant push for improvements in both. One example of a modern solar cell (the term solar cell is used herein for ease and clarity of discussion, but it will be understood that this disclosure applies to any photovoltaic cell in the broadest sense) is formed of a body, typically silicon, in which a p-n junction diode is formed (e.g., by diffusion of an n+ dopant into a surface of the p-type body). In operation, a photon absorbed by the body (e.g., from sunlight) “excites” an atom of the body material causing an increase in the energy of an electron of that atom. This increase in energy moves the electron into the conduction band, where it is free to move around within the semiconductor. The vacancy left by the now mobile electron is called a hole. The negative charge of the electron causes it to flow in one direction within the body (e.g., toward the n-type region), and the positive charge of the hole causes it to flow in the opposite direction (e.g., toward the p-type region). An array of grid lines (parallel lines only and/or intersecting lines) are formed on a surface of the body to permit the collection of the mobile electrons or holes, thereby permitting extraction of a direct current. In some cases, contact pads are provided as terminations for the lines in order to provide a convenient mechanism for connection of the solar cell to external circuitry.

While there are a number of popular solar cell designs on the market today, they generally have in common the grid array on the surface of the body. (As used herein, the term “grid array” shall denote both parallel line and intersecting line embodiments.) For efficient operation of all solar cell designs it is desired to provide a relatively large area within which photons may be absorbed. The electrons and holes generated by the photons cannot travel far without recombining (producing no useful current). Therefore, the grid array must be in electrical contact with (i.e., cover) a significant portion of the body surface. In addition, the lines must have a cross-sectional area sufficient to carry the generated current. Too little an area and the current is attenuated. However, these coverage and size considerations must be balanced by the need to expose as much of the body to photons as possible. That is, the lines shadow or block a portion of the body thereunder, rendering that portion unable to receive photons and generate current. The design goal is then to provide adequate line coverage for current collection while maximizing the body surface exposed to receive photons.

Typically, there has been limited ability to consider the characteristics of the body itself when designing the grid array. That is, a cell designer generally considers the generic attributes of the body on which the grid array is formed, but given the production techniques and need for large-scale production methods, it is generally not possible to consider the specifics of each body and design a unique grid array for that body.

Within the family of silicon body material there are several species. First is single crystal silicon (c-Si). Wafers comprised of this material are very uniform from region to region, and from wafer to wafer, and so there is not a great need to consider the variations across a wafer, or from wafer to wafer, in laying out the grid array. However, c-Si is by far the most expensive member of the Si body family, to the point where cost has prevented an economical integration of that material into commercial solar cells. The second member of the family is multi-crystalline silicon (mc-Si). mc-Si wafers are much less expensive to produce, and therefore much more common in the solar cell industry. But, the structure and quality of mc-Si wafers vary significantly from wafer to wafer and indeed from region to region within a single wafer. This has lead to a generic best-fit approach to grid array layout, in which the balance between current collection and shadowing is considered, but little consideration is given to the physical variations of the wafers themselves. For reasons discussed below, this has led to less than optimized efficiency from mc-Si devices. The third member of the family is a form of mc-Si formed not from an ingot cut into disks, but rather pulled from a molten pool in the form of a ribbon, and hence referred to as ribbon silicon (r-Si). r-Si is the least expensive of the three to produce, but is also the most prone to localized variation (i.e., defects). The individual elements used when producing solar cells from r-Si are technically not wafers, but sections of ribbon. Therefore, we refer to wafers, r-Si ribbon sections and the like generically by the term “body” or “bodies” herein. While r-Si has been used for solar cells, again with a generic approach to grid array design, its inconsistent structure and quality has so far been an obstacle to its acceptance into commercial products.

There are studies in the art suggesting that the grain boundaries of a body from which a solar cell is fabricated be considered when laying out the grid array. According to one such study, a grid array has been applied to a mc-Si body such that the grid lines are located predominantly over grain boundaries. It was demonstrated that this produces an increase in current output as compared to the same array located off of the grain boundaries. One explanation is that the crystallographic boundaries are areas of decreased current generating efficiency, and by locating the lines thereover less of the higher efficiency body material is shadowed by the grid array without limiting the current collection capability (i.e., size) of the grid array. However, each body has a unique grain boundary arrangement, and therefore a grid array design optimized for one body will not likely be optimized for another. The best that can be obtained from such an approach is a consensus mapping in which the average locations of grain boundaries are determined for the group of bodies being processed, and a grid array mask (or screen) formed therefrom for creating the grid array. This may improve, but does not optimize the output of the solar cells produced thereby.

There is therefore a need in the art for a mechanism to take into account the structural and electrical variations from body to body and within a body in the layout of grid arrays (and other elements formed on the surface of such a body) for solar cells and the like. By taking such structural and electric variations into account, it should be possible to provide solar cells with an increased efficiency without requiring a fundamental change in the materials comprising or processes used to form such solar cells.

### SUMMARY

Accordingly, disclosed herein are systems and methods for providing unique grid array layouts on a cell-by-cell and/or body-by-body basis, particularly well suited for the manufacture of solar cells. The systems and methods disclosed herein may be optimized around one or more aspects of the solar cell, such as maximizing current output, maximizing photon absorption, minimizing cost, combinations of such aspects, etc.

According to one aspect of the disclosure each body is mapped for a number of characteristics, such as grain boundaries, sheet resistance, bulk resistance, carrier lifetime, etc. A customized grid array layout is then created for each specific body from an analysis of the mapping, for example a grid array which preferentially is formed over grain boundaries. This working file is then used by a system for forming the grid array, such as a digital lithography system, to produce a grid array on the surface of a body. The grid array is tailored to take into account various characteristics of the specific body on which it is printed. The line width, inter-line spacing, and position of the lines comprising the grid array are configurable on a region-by-region basis.

According to a variation of the above aspect, the digital lithography system may use the analysis of the mapping to directly print the grid array on the surface of the body, or may alternatively print a mask structure used by a plating method, screening method, photo lithography method, etc. as an intermediate step in the production of the grid array.

The above is a summary of a number of the unique aspects, features, and advantages of the present invention. However, this summary is not exhaustive. Thus, these and other aspects, features, and advantages of the present invention will become more apparent from the following detailed description and the appended drawings, when considered in light of the claims provided herein.

### BRIEF DESCRIPTION OF THE DRAWINGS

In the drawings appended hereto like reference numerals denote like elements between the various drawings. While illustrative, the drawings are not drawn to scale. In the drawings:

FIG. 1 is a flow diagram illustrating one embodiment of a method for creating wafer-specific line patterning on the surface of a body, taking into account structural and electrical variations of the body.

FIG. 2 is a photograph of a portion of the surface of a mc-Si solar cell, illustrating macro-level grain patterning.

FIG. 3 is a plan view representation of a body surface showing grain boundaries and line placement to accommodate same according to an embodiment of the present disclosure.

FIG. 4 is a plan view of two grid-array lines formed on the surface of a body, whose width, location and spacing are selected to accommodate underlying structural and electrical variations on a cell-by-cell basis according to an embodiment of the present disclosure.

FIG. 5 is a plan view representation of a body surface showing regions of relatively higher sheet resistance and line placement to accommodate same according to an embodiment of the present disclosure.

FIG. 6 is a perspective view of a body showing regions of relatively higher bulk resistance and line placement to accommodate same according to an embodiment of the present disclosure.

FIG. 7 is a perspective view of a body showing regions of relatively shorter carrier lifetime and line placement to accommodate same according to an embodiment of the present disclosure.

FIG. 8 is a plan view of a portion of a body surface illustrating variation of the line width, location, and spacing for a body characterized, not on a cell-by-cell basis, but rather on as a whole, to accommodate, structural and electrical variations on a body-to-body basis according to an embodiment of the present disclosure.

### DETAILED DESCRIPTION

The present disclosure takes advantage of a process for in situ formation or masking of wafer-level structures known as digital lithography, and effectively uses a map of a body to print a grid array thereon in a pattern unique to that body. Digital lithography is a maturing technology designed to reduce the costs associated with photolithographic processes, used often in the fabrication of micro-electronic devices, integrated circuits, and related structures. Digital lithography directly deposits patterned material onto a substrate in place of the delicate and time-consuming photolithography processes used in conventional manufacturing processes. The printed pattern produced by digital lithography can either comprise actual device features (i.e., elements that will be incorporated into the final device or circuitry, such as electrical interconnection lines, contact pads, the source, drain, and gate regions of thin film transistors, opto-electronic device components, etc.) or it can be a mask for subsequent semiconductor processing (e.g., etch, implant, plating, deposition, etc.) Importantly, unlike traditional lithographic systems, digital lithography systems avoid the cost and challenges associates with the use of reticles or masks while at the same time provide great flexibility in varying the printing from one device to the next.

Typically, digital lithography involves depositing a print material by moving a print head and a substrate relative to one another along a single axis (the “print travel axis”). Print heads, and in particular, the arrangements of the ejectors incorporated in those print heads, are optimized for printing along this print travel axis. Printing takes place either in a raster fashion, with the print head making “printing passes” across the substrate as the ejector(s) in the print head dispense individual “droplets” of print material onto the substrate or in a single pass mode if the ejector spacing is smaller than the critical dimension. Typically, the print head moves relative to the substrate in each printing pass, but the equivalent result may be obtained if the substrate is caused to move relative to the print head (for example, with the substrate secured to a moving stage) in a printing pass. At the end of each printing pass, the print head (or substrate) makes a perpendicular shift relative to the print travel axis before beginning a new printing pass. Printing passes continue in this manner until the desired pattern has been fully printed onto the substrate.

Materials typically printed by digital lithographic systems include phase change material and solutions of polymers, colloidal suspensions, such suspensions of materials with desired electronic properties in a solvent or carrier. For example, U.S. Pat. Nos. 6,742,884 and 6,872,320 (each incorporated herein by reference) teach a system and process, respectively, for printing a phase change material onto a substrate for masking. According to these references, a suitable material, such as a stearyl erucamide wax, is maintained in liquid phase over an ink-jet style piezoelectric print head, and selectively ejected on a droplet-by-droplet basis such that droplets of the wax are deposited in desired locations in a desired pattern on a layer formed over a substrate. The droplets exit the print head in liquid form, then solidify after impacting the layer, hence the material is referred to as phase-change.

Once dispensed from an ejector, a print material droplet attaches itself to the substrate through a wetting action, then proceeds to solidify in place. In the case of printing phase-change materials, solidification occurs when a heated and liquefied printed droplet loses its thermal energy to the substrate and/or environment and reverts to a solid form. In the case of suspensions, after wetting to the substrate, the carrier most often either evaporates leaving the suspended material on the substrate surface or the carrier hardens or cures. The thermal conditions and physical properties of the print material and substrate, along with the ambient conditions and nature of the print material, determine the specific rate at which the deposited print material transforms from a liquid to a solid, and hence the height and profile of the solidified deposited material.

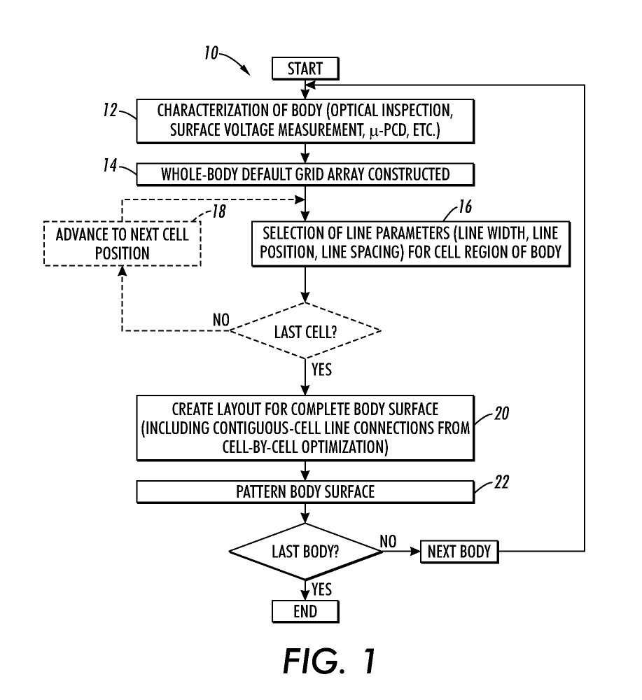

If two adjacent droplets are applied to the substrate within a time prior to the solidification of either or both droplets, the droplets may wet and coalesce together to form a single, continuous printed feature. Surface tension of the droplet material, temperature of the droplet at ejection, ambient temperature, and substrate temperature are key attributes for controlling the extent of droplet coalescence and lateral spreading of the coalesced material on the substrate surface. These attributes may be selected such that a desired feature size (e.g., width) may be obtained. Now, with reference to FIG. 1, a first embodiment of a method 10 for wafer-specific line patterning for solar cells and the like according to the present disclosure begins with the step 12 of characterizing a body which is to be formed into a solar cell. We describe this embodiment in terms of a multi-crystalline silicon (mc-Si) body, which will typically be processed in wafer form, However, as other such body materials may virtually equivalently be substituted for mc-Si, the present disclosure shall not be interpreted to be limited to such a starting material. Furthermore, while there are many preliminary steps in the preparation of a body for processing into a solar cell, we will focus here only on those steps affected by the present invention.

The step 12 of characterizing the body may comprise examining regions (cells) of the body or the entire body for one or more different characteristics which impact the photovoltaic process. Examples of these characteristics include the location of grain boundaries, sheet resistance, bulk resistance, and carrier lifetime. Each of these characteristics are discussed below in terms of the nature of the characteristic, its impact on the photovoltaic process of the body, and considerations associated with that characteristic when laying out a grid array. While these specific characteristics are discussed, it will be appreciated that other such characteristics may equivalently be examined and considered when performing a grid array layout on a body-by-body basis.

According to one embodiment disclosed herein, a default grid pattern is constructed at step 14, such as in a computer-controlled layout program. The default parameters of the grid pattern include the number of lines to be applied, the width of those lines, the location of those lines, the line-to-line spacing, etc. If the body is characterized on a cell-by cell basis, then the default grid pattern is constructed over a grid where each element of the grid represent a cell characterized in step 12. At step 16, the parameters of the grid pattern may be modified to account for one or more of the characteristics determined by step 12. For example, modeling software may be used to model the layout then shift the position of a line. The effect of this shift is examined to determine if it improves or reduces the efficiency of the cell (such as, does the shifted location more efficiently place the line over a grain boundary). Once the desired parameters are examined and preferred parameters identified, they are selected. This process proceeds on a cell-by-cell basis (if the body is characterized in such a manner), advancing to the next cell to be examined at step 18. If the body is not characterized on a cell-by-cell basis, the examination and selection of the preferred grid line parameters are performed for the body as a whole. (For this reason, the advancement to the next cell at step 18 is shown as dashed in FIG. 1, indicating an optional step.)

Once the examination and selection of the line parameters is completed, the layout of the grid array for the entire body surface is performed at step 20. If the body is characterized on a cell-by-cell, then the line layout for contiguous cells in the long axis of the lines are resolved such that they are in electrical contact with one another. That is, any adjustments in width and position required to adequately connect the grid-level segments of the lines are performed. Depending on the application and embodiment of the disclosed method, it may also be necessary to adjust line widths, positions, etc. to accommodate other features formed on the body surface, such as contact pads, mounting points, etc. Once the final layout is complete, the grid array may then be patterned by, for example, a digital lithography process, at step 22. In an appropriate embodiment, the next body in then selected and the above method repeated.

From the above, it should be understood than one element of the method disclosed is the examination, characterization, and/or mapping of the body, or cells thereof, for various attributes, impurities, crystallographic defects, etc. which affect the photo-generative efficiency of the body. Each body may be examined, characterized, and/or mapped for many such attributes, impurities, crystallographic defects, etc., including the following.

Location of Grain Boundaries

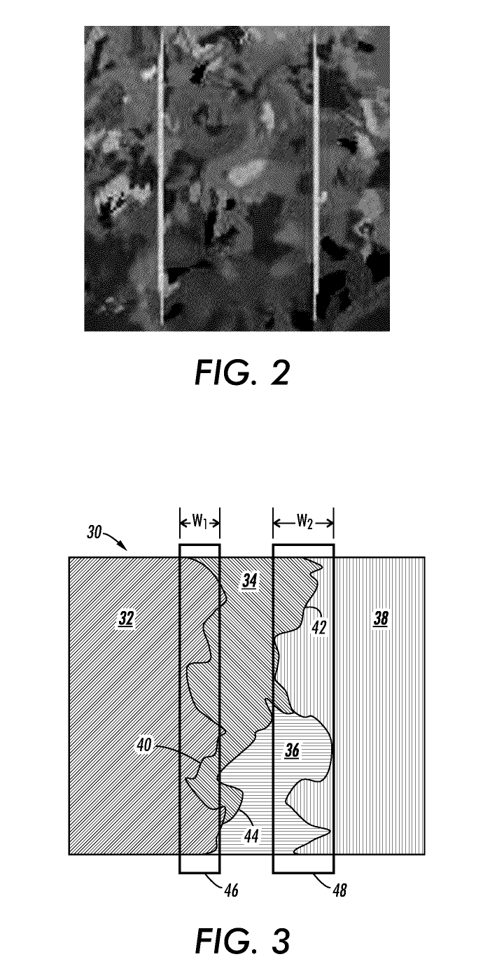

mc-Si is, by definition, comprised of a matrix of individual silicon crystals. The crystals (also referred to as grains) are held together by covalent bonds, but distinct boundaries between the grains exist. While typically each grain boundary is a microscopic entity, an aggregation of grain boundaries can be viewed macroscopically and without the aid of a microscope, as illustrated in FIG. 2. Adjacent light and dark regions shown in the figure are separated by a grain boundary.

The grain boundaries in a mc-Si body are locations at which photons do not efficiently generate electron-hole pairs. The likelihood of non-generative carrier recombination increases at the boundary, primarily due to the nature of the material structure at that location. Therefore, by placing grid array lines selectively over grain boundaries, the less efficient body regions are shadowed by the lines. Consequently, the more efficient regions of the body are not shadowed, meaning an increase in the carrier generation, i.e., an increase in efficiency. Beneficially, the ability to provide a unique grid array for each body means that the grid array may be placed on the specific grain boundary regions of a body, as opposed to merely a consensus arrangement which considers the grain boundary orientation of large number of wafers and is not tailored to any one specific grain boundary pattern.

The size of a grain boundary varies with the material from which the body is formed, the processes employed to form the body, and a number of other factors. However, the grain boundary is large enough to be recognized by visual inspection (typically non-microscopic), yet small enough to be covered by the average line width (on the order of 150 microns). Therefore, the body is visually examined, and recognition software employed to determine the physical locations of the grain boundaries. In one embodiment, grain boundary location is the sole characteristic used to determine the desired location of the grid array, while in other embodiments grain boundary is used together with other aspects of the body to determine the desired location of the grid array. The body is divided up into regions, referred to as cells, and a grid array is laid out which maximizes coverage of grain boundaries within that cell. FIG. 3 is an illustration of a cell 30 having grain regions 32, 34, 36, 38 with differing crystallographic orientation, separated by grain boundaries 40, 42, and 44. According to this disclosure, cell 30 is examined, and the location of grain boundaries 40, 42, and 44 determined. In one example, it is determined that the primary axis of boundaries 40 and 42 are relatively parallel to a desired axis of the grid array (e.g., the overall grid array on the cell has an x-y orientation and the portion of grain boundaries 40, 42 within cell 30 is generally oriented in either the x or y axis). For illustration purposes, we assume that it is known that cell 30 should have 2 lines 46, 48 of the grid array extending therethrough (the precise number of such lines is not material to the present invention). Accordingly the system then selects the width of line 46 and 48 to be a default starting width. They are also located at a default location and default spacing apart from one another. The lines are superimposed over the cell, and compared to the location of the grain boundaries 40, 42. The locations, widths, and inter-line spacing are adjusted within permissible limits until the line 46 optimally covers boundary 40 and line 48 optimally covers boundary 42.

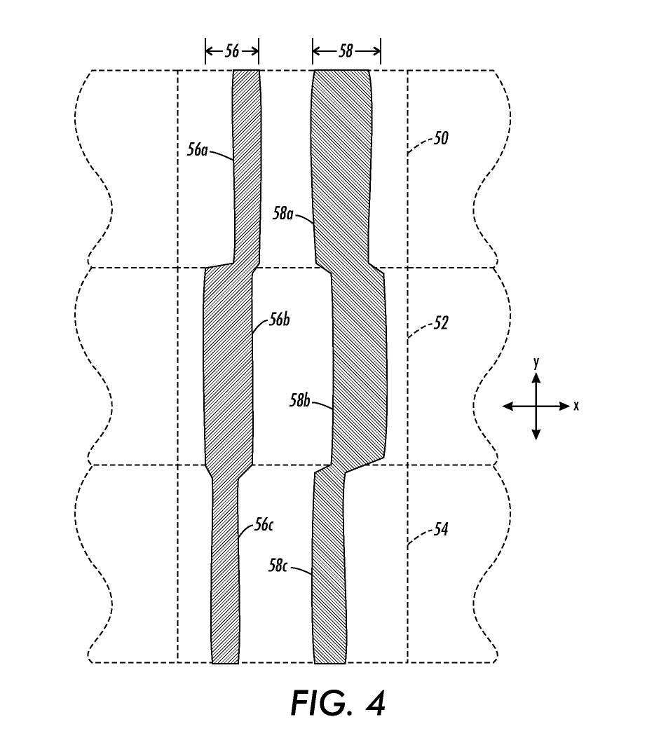

A cell-by-cell examination of the body takes place in this manner until the entire body is laid out for the production of a grid array. It is important to note that while the line location, width, and spacing may be unique from cell to cell, there is electrical continuity required between contiguous cells in the grid array axis direction. That is, lines in one cell must connect to the next. This is illustrated in FIG. 4, in which three contiguous cells 50, 52, 54, aligned in the y-direction of the grid array are shown. Each cell has two lines 56, 58 extending therethrough. Each line 56, 58 is made up of individual segments 56a, 56b, 56c, 58a, 58b, 58c, respectively, and while for each line 56, 58 those segments must make electrical contact with one another, they need not be in the same position as, have the same width as, nor have the same inter-cell spacing from the other segments of that line. Rather, the segments are permitted to vary in order that they most effectively cover grain boundaries in their respective cells.

It is known that each line comprising the grid array must have a certain current carrying capacity in order to effectively provide a current path for the photo-generated current. If the lines are too thin or narrow current blocking occurs and the conductance of the lines decrease due to heat loss. Therefore, while there will be limits on the minimum size of the lines which causes shadowing of the underlying body material, the placement of the lines may compensate by covering areas of the body with reduced efficiency for current generation.

It will now be appreciated that the mapping of the body combined with the flexibility of application of the grid array by digital lithography permits the placement of the grid array preferably over grain boundaries in materials such as mc-Si and r-Si. In so doing, the shadowing of the higher efficiency body material is reduced, rendering a more efficient solar cell. As next described, this same concept can be applied to other characteristics of the body, considered alone or in combination, to provide a solar cell with improved efficiency as compared to previously known methods and systems.

Sheet Resistance

N+ layer sheet resistance (or surface resistivity) is a measure of resistance of a thin film of uniform thickness. For an electric current flowing across a surface, it is the ratio of DC voltage drop per unit length to the surface current per width. In effect, the sheet resistance is the resistance between two opposite sides of a square of the subject material, and is independent of the size of the square or its dimensional units. Sheet resistance provides information about the electrical characteristics of the N+ thin layer near the surface of a body. It is affected by grain structure, impurities, vacancies, lattice mismatch, and a number of other structural defects near the surface of the body. Regions of a body having a high sheet resistance will trap carriers for non-generative recombination (i.e., contribute to the inefficiency of the generation of current from photons). Just as the inefficient grain boundary areas described above are convenient places to locate a grid array line, so too are the areas of relatively higher sheet resistance.

Sheet resistance can be measured using the surface photovoltage method. According to this method the potential of the body surface is monitored while electron-hole pairs are generated with a light source. This monitoring can be done on a cell-by-cell basis, and a map created therefrom of the entire body surface's sheet resistance. In one embodiment, sheet resistance is the sole characteristic used to determine the desired location of the grid array, while in other embodiments sheet resistance is used together with other aspects of the body to determine the desired location of the grid array.

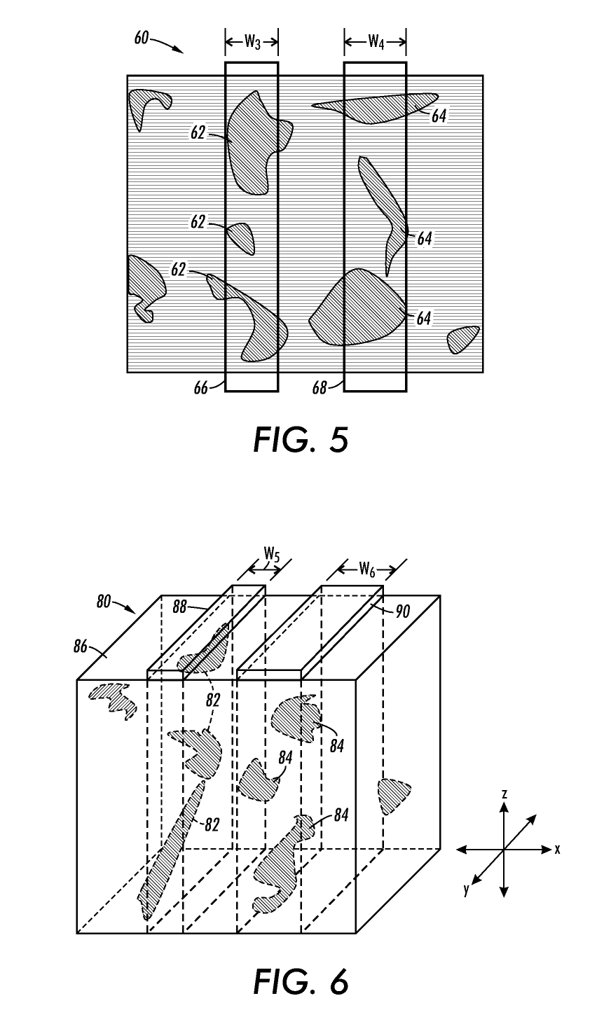

The body is again divided up into cells. FIG. 5 is an illustration of a cell 60 having groupings 62, 64 of regions of relatively higher sheet resistance than the remainder of the cell. According to this disclosure, cell 60 is examined, and the surface mapping of sheet resistance is determined. In one example, it is determined that the various regions of higher sheet resistance can be organized by orientation into groupings regions 62 and 64, respectively, for example by a centroid-line fit algorithm, with primary axes of those groupings relatively parallel to a desired axis of the grid array (e.g., the overall grid array on the cell has an x-y orientation and regions of higher sheet resistance are organized so as to present axes generally oriented parallel to either the x or y axis).

For illustration purposes, we assume that it is known that cell 60 should have 2 lines 66, 68 of the grid array extending therethrough (the precise number of such lines is not material to the present invention). Again, the system may select default line parameters including the width of, location of, and spacing between lines 66 and 68. The lines are superimposed over the cell, and compared to the location of the groupings 62, 64. The line parameters are adjusted within permissible limits until the line 66 optimally covers grouping 62 and line 68 optimally covers grouping 64.

A cell-by-cell examination of the body takes place in this manner until the entire body is laid out for the production of a grid array, with the lines for each cell electrically communicating with the lines of contiguous cells in the direction of the lines. Again, it will now be appreciated that the mapping of the body combined with the flexibility of application of the grid array by digital lithography permits the placement of the grid array preferably over regions of relatively higher sheet resistance. In so doing, the shadowing of the higher efficiency body material is reduced, rendering a more efficient solar cell.

Bulk Resistance

Bulk resistance (or volume resistance) is similar to sheet resistance, but takes into account the area being measured. Thus, the units for bulk resistance are ohm-cm, as opposed to the units for sheet resistance which are ohms-per-square. Bulk resistance provides information about the electrical characteristics a region of a body. It is also affected by grain structure, impurities, vacancies, lattice mismatch, and a number of other structural defects within the body. Regions of a body having a relatively higher bulk resistance will trap carriers for non-generative recombination (i.e., contribute to the inefficiency of the generation of current from photons). Just as the inefficient grain boundary areas and areas of relatively higher sheet resistance described above are convenient places to locate a grid array line, so too are the areas above regions of relatively higher bulk resistance.

Bulk resistance can also be measured using the surface photovoltage method. For bulk measurements, the potential of the body surface is monitored while electron-hole pairs are generated with a light source. This measurement can be done before any layers are formed on the silicon surface. Bulk resistance differs from sheet resistance in that while sheet resistance relates to the N+ layer that is formed on top of the bulk silicon, the bulk resistance relates to the bulk silicon over which the N+ layer is formed. This monitoring can be done on a cell-by-cell basis, and a map created therefrom of the entire body's bulk resistance. In this embodiment, a cell is typically a rectangular volume, extending the depth of the body. In one embodiment, bulk resistance is the sole characteristic used to determine the desired location of the grid array, while in other embodiments bulk resistance is used together with other aspects of the body to determine the desired location of the grid array.

FIG. 6 is an illustration of a cell 80 having groupings 82, 84 of regions of relatively higher bulk resistance than the remainder of the cell. According to this disclosure, cell 80 is examined, and the surface 86 of cell 80 mapped to determine bulk resistance. In one example, it is determined that the various regions of higher bulk resistance can be organized by orientation into groupings regions 82 and 84, respectively, for example by a centroid-line fit algorithm, with primary planes of those groupings relatively parallel to the y-z-plane of the grid array (e.g., the overall grid array on the cell has an x-y orientation and regions of higher sheet resistance are organized so as to present axes generally oriented parallel to the y axis and disposed vertically thereunder).

For illustration purposes, we again assume that it is known that cell 80 should have 2 lines 88, 90 of the grid array extending therethrough (the precise number of such lines is not material to the present invention). The system may select default line parameters including the width of, location of, and spacing between lines 88 and 90. The lines are superimposed over the cell, and compared to the location of the groupings 82, 84. The line parameters are adjusted within permissible limits until the line 88 optimally covers grouping 82 and line 90 optimally covers grouping 84.

A cell-by-cell examination of the body takes place in this manner until the entire body is laid out for the production of a grid array, with the lines for each cell electrically communicating with the lines of contiguous cells in the direction of the lines. Again, the mapping of the body combined with the flexibility of application of the grid array by digital lithography permits the placement of the grid array preferably over regions of relatively higher bulk resistance. In so doing, the shadowing of the higher efficiency body material is reduced, rendering a more efficient solar cell.

Carrier Lifetime

Minority carrier lifetime is defined as the average time it takes an excess minority carrier to recombine. Once an electron-hole pair is created by absorption of a photon the electron and hole separate from one another and each migrates toward a region of opposite polarity. Each carrier car migrate for a certain amount of time (or distance) before it recombines with an opposite carrier and converts its energy into heat or light. The length of time (and hence distance) that a carrier can migrate is a function in part of the material within which the carrier travels. Typically, for silicon, the carrier lifetime is a function of the quality of the silicon body. Impurities and crystalline defects contribute to reduced carrier lifetime. Therefore, regions of a body containing impurities or crystalline defects will typically have reduced carrier lifetime as compared with other regions of the body.

In regions of reduced carrier lifetime carriers must reach the N+ layer sooner if they are not to be lost to recombination. Accordingly, interconnection lines can be narrower in regions of reduced carrier lifetime due to lower current density. It is not an optimal solution to base an entire grid array line spacing on the spacing required for the shortest carrier lifetime. Indeed, it would be optimal to base line spacing, location, and width on carrier lifetime for each individual cell.

Carrier lifetime can be measured using the microwave photoconductive decay (μ-PCD) method. Essentially, a body under test is bombarded with microwaves while the body is exposed to light. Local variations in photoconductance produce variations in the microwave transmission, which may be measured by an appropriate detector. This monitoring can be done on a cell-by-cell basis, and a map created therefrom of the entire body's carrier lifetime. In this embodiment, a cell is typically a rectangular volume, extending the depth of the body. In one embodiment, carrier lifetime is the sole characteristic used to determine the desired location of the grid array, while in other embodiments carrier lifetime is used together with other aspects of the body to determine the desired location of the grid array.

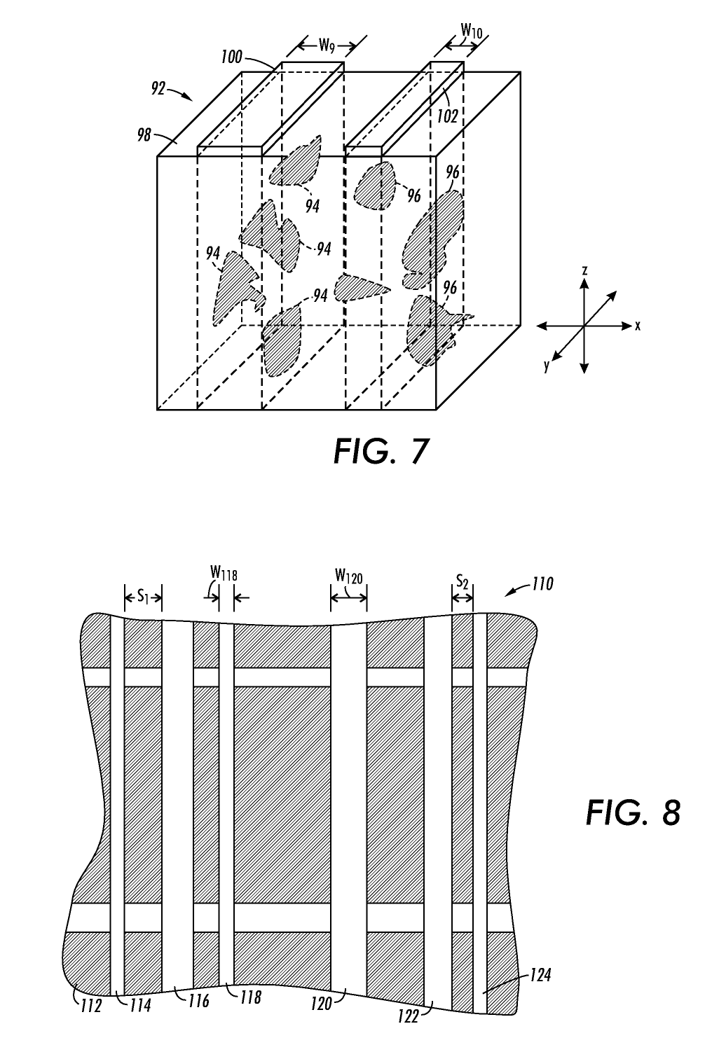

FIG. 7 is an illustration of a cell 92 having groupings 94, 96 of regions of reduced lifetimes (that is, regions in which minority carriers will have shorter lifetimes as compared to other regions of the body). According to this disclosure, cell 92 is examined and mapped to determine the reduced lifetime regions. In one example, it is determined that the various regions of reduced lifetime can be organized by orientation into groupings regions 94 and 96, respectively, for example by a centroid-line fit algorithm, with primary planes of those groupings relatively parallel to the y-z-plane of the grid array (e.g., the overall grid array on the cell has an x-y orientation and regions of reduced lifetime are organized so as to present axes generally oriented parallel to the y axis and disposed vertically thereunder).

For illustration purposes, we again assume that it is known that cell 98 should have 2 lines 100, 102 of the grid array extending therethrough (the precise number of such lines is not material to the present invention). The system may select default line parameters including the width of, location of, and spacing between lines 100 and 102. The lines are superimposed over the cell, and compared to the location of the groupings 94, 96. The line parameters are adjusted within permissible limits until the line 100 optimally covers grouping 94 and line 102 optimally covers grouping 96.

A cell-by-cell examination of the body takes place in this manner until the entire body is laid out for the production of a grid array, with the lines for each cell electrically communicating with the lines of contiguous cells in the direction of the lines. The mapping of the body combined with the flexibility of application of the grid array by digital lithography permits the placement of the grid array preferably over regions of short lifetime. In so doing, the shadowing of the higher efficiency body material is reduced, rendering a more efficient solar cell. In addition, the line width and number of lines may be optimized such that lines are located closer to reduced lifetime regions. Again, this results in reduced shadowing of higher performing regions of the body, improving photon conversion efficiency of the resulting solar cell.

It will now be appreciated that a method and system is disclosed which permits characterization of a body for a number of different performance parameters, generation of a grid array layout which provides variable grid line size, location, and spacing in order to take into account the local variations of the performance parameters, and form a grid array on the surface of the body such that improved photo-generative efficiency is provided. In creating the layout, one parameter may be considered more critical than others, and the layout then optimized around that parameter. For example, from a designer's perspective it may be of critical importance to place lines preferentially over grain boundaries, while of a lesser importance to consider the sheet and bulk resistivities. Alternatively, a designer may use all of the characterizations as secondary considerations, focusing on one or more aspects of the solar cell, such as maximizing current output, maximizing photon absorption, minimizing cost, combinations of such aspects, etc., or other aspects of the device manufacturing process or apparatus while still providing some level if customization for cell-to-cell and/or body-to-body variations.

The description above has focused on the embodiment in which a body is divided into a matrix of cells, and the structural and electrical characteristics of each cell are evaluated individually. With these evaluations, grid array line layout can then be made on a cell-by-cell basis. However, according to another embodiment of this disclosure, the evaluation of the structural and electrical variations are made on a body-by-body basis, allowing for grid array line layout consistent across an entire body, but unique from one body to the next. With reference to FIG. 8, there is shown therein a portion of body 110 having formed on its surface 112 a plurality of grid array lines 114-124. It is assumed that body 110 has been previously characterized, and that the layout of the grid array has taken into account the various structural and electrical characteristics of the body. This has resulted in variations in line width (e.g., W₁₂₀>W₁₁₈, etc.), line spacing (e.g., S₁>S₂, etc.), and line placement across surface 112. Importantly, according to the present disclosure, the particular grid array layout for body 110 may be unique for that body and its structural and electrical characteristics. Another body will have its own unique grid array layout, with unique line widths, spacing, and locations as a function of the particular structural and electrical characteristics of that body.

The physics of modern electrical devices and the methods of their production are not absolutes, but rather statistical efforts to produce a desired device and/or result. Even with the utmost of attention being paid to repeatability of processes, the cleanliness of manufacturing facilities, the purity of starting and processing materials, and so forth, variations and imperfections result. Accordingly, no limitation in the description of the present invention or its claims can or should be read as absolute. The limitations of the claims are intended to define the boundaries of the present invention, up to and including those limitations. To further highlight this, the term “substantially” may occasionally be used herein in association with a claim limitation (although consideration for variations and imperfections is not restricted to only those limitations used with that term). While as difficult to precisely define as the limitations of the present invention themselves, we intend that this term be interpreted as “to a large extent”, “as nearly as practicable”, “within technical limitations”, and the like.

Furthermore, while a plurality of preferred exemplary embodiments have been presented in the foregoing detailed description, it should be understood that a vast number of variations exist, and these preferred exemplary embodiments are merely representative examples, and are not intended to limit the scope, applicability or configuration of the invention in any way. For example, the above disclosure begins with a default line position, width, and spacing for each cell, then iteratively examines variations thereon until an optimized set of line parameters is obtained. However, it is within the scope of the present disclosure that the characteristics of the body be examined, and line parameters directly determined therefrom without the iterative process. Alternatively, an H-pattern may initially be provided, then additional lines added for example over grain boundaries. A cell-by-cell analysis (e.g., Monte-Carlo algorithm) can then be made as to whether the benefit of a cell segment of the line outweighs the cost (e.g., improved efficiency exceeds shadow effect). Thus, the line placement methodology is but one of a wide number of implementation choices as opposed to a fundamentally different inventive concept.

In addition, an ejector-based deposition system has been described for the formation of the grid array. However, other such digital lithography systems may also be employed, such as laser direct imaging and the like. Therefore, the foregoing detailed description provides those of ordinary skill in the art with a convenient guide for implementation of the invention, and contemplates that various changes in the functions and arrangements of the described embodiments may be made without departing from the spirit and scope of the invention defined by the claims thereto.

What is claimed is:

1. A method of forming a grid array on the surface of a solar cell comprising:
measuring the structural and electrical characteristics of a body from which the solar cell is to be formed;
determining a desired width, location, and spacing of the lines comprising the grid array based on the measured structural and electrical characteristics of said body;
creating a layout for the lines comprising the grid array based on the determined desired width, location, and spacing thereof such that said layout is unique for said body its structural and electrical characteristics; and
patterning the surface of the body for a grid array based on said layout.

2. The method of claim 1, wherein said patterning is performed by digital lithography.

3. The method of claim 2, wherein said digital lithography deposits, on a droplet-by-droplet basis a mask used to form a pattern of the lines of the grid array.

4. The method of claim 2, wherein said digital lithography directly deposits, on a droplet-by-droplet basis, the lines of the grid array.

5. The method of claim 1, wherein said patterning the surface of the body is performed using laser direct imaging.

6. The method of claim 1, wherein said step of determining a desired width, location, and spacing of the lines comprises creating a default grid array for the body, then modifying specific line parameters to locally account for variations in the structural and electrical characteristics of the body.

7. The method of claim 6, where said body is divided up into a plurality of cells, and further wherein steps of measuring the structural and electrical characteristics of said body, determining desired width, location, and spacing of lines of the grid array, and creating a layout for the lines takes place on a cell-by-cell basis.

8. The method of claim 7, wherein said step of creating a layout for the lines comprises creating a layout for the lines on a cell-by-cell basis and creating a layout for the entire body surface by assembling the layout for each cell and ensuring electrical continuity between same where appropriate.

9. The method of claim 1 wherein the measured structural and electrical characteristics of the body include one such characteristic selected from the group consisting of: grain boundary location within the body, sheet resistance of regions of the body, bulk resistance of regions of the body, and carrier lifetime for regions of the body.

10. The method of claim 9, wherein said measured structural and electrical characteristics of the body include a plurality of said characteristics, and further wherein said step of determining a desired width, location, and spacing of the lines comprising the grid array based on the measured structural and electrical characteristics of said body comprises taking into account the plurality of characteristics to arrive at a single desired width, location, and spacing of the lines.

11. An apparatus for forming a grid array on the surface of a solar cell comprising:
a test apparatus for measuring the structural and electrical characteristics of a body from which the solar cell is to be formed;
a modeling software component for determining a desired width, location, and spacing of the lines comprising the grid array based on the measured structural and electrical characteristics of said body;
a layout software component for creating a layout for the lines comprising the grid array based on the determined desired width, location, and spacing thereof such that said layout is unique for said body its structural and electrical characteristics; and
a deposition and patterning system for creating on the surface of the body a pattered grid array based on said layout.

12. The apparatus of claim 11, wherein said deposition and patterning system includes a digital lithography subsystem.

13. The apparatus of claim 12, wherein said digital lithography includes a print head which deposits, on a droplet-by-droplet basis, a mask used to form a pattern of the lines of the grid array.

14. The apparatus of claim 12, wherein said digital lithography includes a print head which directly deposits, on a droplet-by-droplet basis, the lines of the grid array.

15. The apparatus of claim 11, wherein said deposition and patterning system includes a laser direct imaging subsystem.

16. The apparatus of claim 11, wherein said modeling software creates a default grid array for the body, then modifies specific line parameters to locally account for variations in the structural and electrical characteristics of the body.

17. The apparatus of claim 16, wherein:
said test apparatus divides said body into a plurality of cells, and measures the structural and electrical characteristics on a cell-by-cell basis;
said modeling software determines desired width, location, and spacing of lines of the grid array on a cell-by-cell basis; and
said layout software creates a layout for the lines on a cell-by-cell basis.

18. The apparatus of claim 17, wherein said step of creating a layout for the lines comprises:
creating a layout for the lines on a cell-by-cell basis; and
creating a layout for the entire body surface by assembling the layout for each cell and ensuring electrical continuity between same where appropriate.

19. The apparatus of claim 11 wherein said test apparatus is configured to measure structural and electrical characteristics of the body which comprise one such characteristic selected from the group consisting of: grain boundary location within the body, sheet resistance of regions of the body, bulk resistance of regions of the body, and carrier lifetime for regions of the body.

20. The apparatus of claim 19, wherein said test apparatus is configured to measure structural and electrical characteristics of the body comprising a plurality of said characteristics, and further wherein said modeling software component determines a desired width, location, and spacing of the lines comprising the grid array taking into account the plurality of said characteristics to arrive at a single desired width, location, and spacing of the lines.
